(19) United States
(12) Patent Application Publication
(10) Pub. No.: US 2014/0151872 A1
(43) Pub. Date: Jun. 5, 2014

(54) SEMICONDUCTOR MODULE

(71) Applicants: Takaoki Ogawa, Toyota-shi Aichi-ken (JP); Makoto Imai, Toyota-shi Aichi-ken (JP); Shizuyasu Matsubayashi, Toyota-shi Aichi-ken (JP)

(72) Inventors: Takaoki Ogawa, Toyota-shi Aichi-ken (JP); Makoto Imai, Toyota-shi Aichi-ken (JP); Shizuyasu Matsubayashi, Toyota-shi Aichi-ken (JP)

(73) Assignee: TOYOTA JIDOSHA KABUSHIKI KAISHA, Toyota-shi Aichi-ken (JP)

(21) Appl. No.: 14/095,592

(22) Filed: Dec. 3, 2013

(30) Foreign Application Priority Data
Dec. 5, 2012 (JP) 2012-266109

(51) Int. Cl. H01L 23/40

(52) U.S. Cl. CPC H01L 23/4093
USPC 257/719

(57) ABSTRACT

A semiconductor module includes semiconductor device, at least one cooler, at least one fastening member. The semiconductor device has a flat shape. The at least one cooler is arranged adjacent to the semiconductor device. The at least one fastening member has a pressure-contact part that is configured to apply a pressure to the at least one cooler. Furthermore, the at least one fastening member fastens a layered body including the semiconductor device and the at least one cooler in a layer direction of the layered body. A dent configured to accommodate the pressure-contact part is provided in the at least one cooler.

### INCORPORATION BY REFERENCE

The disclosure of Japanese Patent Application No. 2012-266109 filed on Dec. 5, 2012 including the specification, drawings and abstract is incorporated herein by reference in its entirety.

### BACKGROUND OF THE INVENTION

1. Field of the Invention

The invention relates to a semiconductor module.

2. Description of Related Art

A semiconductor module, in which coolers are arranged on both sides of a flat semiconductor device to cool a semiconductor device which generates a large amount of heat such as a switching device for driving a motor of an electric vehicle efficiently, has been known. A layered body constituted by the semiconductor device and the coolers is fastened with fastening elements. The fastening elements are typically screws or bolts/nuts (Japanese Patent Application Publication No. 2012-033864 (JP 2012-033864 A), Japanese Patent Application Publication No. 2007-273884 (JP 2007-273884 A), Japanese Patent Application Publication No. H11-187642 (JP H11-187642 A)).

### SUMMARY OF THE INVENTION

When the semiconductor module is arranged near an engine or a motor of an electric vehicle, the semiconductor module may be sometimes exposed to a higher ambient temperature than the normal temperature due to heat from the engine or the motor. That is, the semiconductor module may be used in an environment where a temperature change of the surrounding is severer than a temperature change under the normal temperature. Such a severe temperature change may affect the fastening members. The present invention provides a semiconductor module which relaxes the temperature change generated in the fastening members due to the changes in the ambient temperature.

The semiconductor module according to an aspect of the present invention includes a semiconductor device, at least one cooler and at least one fastening element. The semiconductor device has a flat shape. The at least one cooler is arranged adjacent to the semiconductor device. The at least one fastening member has a pressure-contact part configured to apply a pressure to the at least one cooler. Furthermore, the at least one fastening member fastens a layered body including the semiconductor device and the at least one cooler in a layer direction of the layered body. A dent configured to accommodate the pressure-contact part of the at least one fastening member is provided in the at least one cooler.

### BRIEF DESCRIPTION OF THE DRAWINGS

Features, advantages, and technical and industrial significance of exemplary embodiments of the invention will be described below with reference to the accompanying drawings, in which like numerals denote like elements, and wherein:

FIG. 1 is an exploded perspective view of a semiconductor module according to an embodiment;

FIG. 2 is a perspective view of a semiconductor module according to an embodiment;

FIG. 3 is a sectional view taken along the line in FIG. 2;

FIG. 4 is a sectional view of a semiconductor module according to a second embodiment;

FIG. 5 is a sectional view of a semiconductor module according to a third embodiment; and

FIG. 6 is a sectional view of a semiconductor module according to a fourth embodiment.

### DETAILED DESCRIPTION OF EMBODIMENTS

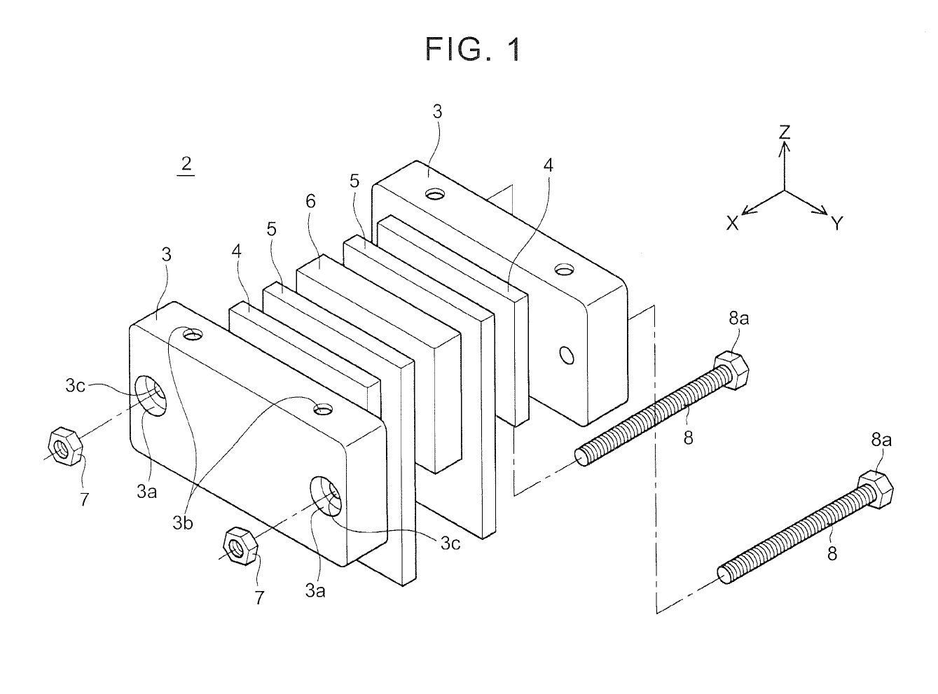

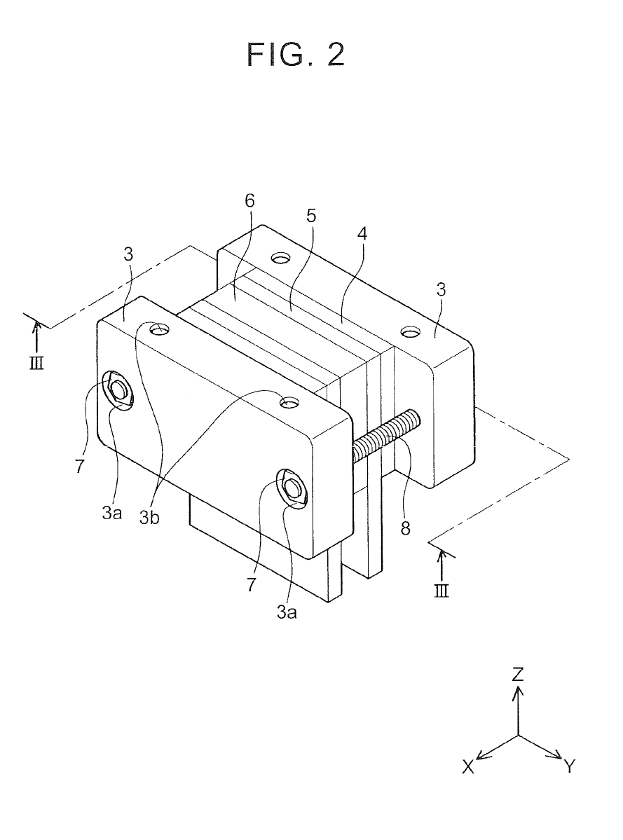

A semiconductor module of an embodiment of the present invention will be described with reference to the accompanying drawings. FIG. 1 shows an exploded perspective view of a semiconductor module 2 and FIG. 2 shows a perspective view of the semiconductor module 2. The semiconductor module 2 includes a semiconductor device 6, electrode plates 5 and insulating plates 4. The electrode plates 5 are arranged on both sides of the flat semiconductor device 6. The insulating plates 4 are arranged outside of the electrode plates 5. Coolers 3 are arranged outside of the insulating, plates 4. In other words, the coolers 3 are arranged on both sides of and adjacent to the semiconductor device 6. As shown in FIG. 2, “adjacent to” may include a case where the electrode plate 5 and the insulating plate 4 exist between the semiconductor device 6 and the cooler 3. A layered body which includes the semiconductor device 6, the electrode plates 5, the insulating plates 4, and the coolers 3 is fastened with two bolts 8 and nuts 7.

The semiconductor device 6 is a transistor formed on a substrate of for example, silicon carbide (SiC). A surface electrode (terminal) is exposed on both sides of the flat plate thereof and the periphery of the surface electrode is covered with molded resin. In FIGS. 1 to 6, respective components such as the semiconductor device, the surface electrodes and the resin are not represented individually but the semiconductor device 6 is represented simply with a single rectangular parallelepiped. The semiconductor module 2 is used in, for example, a switching circuit of an inverter. The semiconductor device 6 includes three terminals (emitter, collector, and gate) and the surface electrode corresponds to the emitter and the collector in which a large current flows.

In FIGS. 1 to 6, depiction of the electrode which corresponds to the gate is omitted. In addition, the semiconductor device 6 may include a reflux diode which is connected to a transistor in an antiparallel direction.

The electrode plates 5 are arranged on both sides of the semiconductor device 6 such that those electrodes 5 contact the surface electrodes of the semiconductor device 6. As shown in the Figure, the electrode plate 5 is larger than the semiconductor device 6 and a metallic flat conductor called bus bar is connected to this electrode plate 5. The semiconductor device 6 is electrically connected to other devices via the electrode plates 5 and the bus bar (not shown).

The insulating plates 4 are inserted to implement insulation between the electrode plate 5 and the cooler 3. The insulating plates 4 are made of ceramics.

The coolers 3 are arranged on both sides of the semiconductor device 6 to cool the semiconductor device 6. The cooler 3 is a flat hollow member in which coolant flows. That is, the cooler is a hollow member having a passage for the coolant internally. A casing of the cooler is made of aluminum or copper having a high thermal conduction coefficient.

Holes 3b for supplying/discharging coolant are provided on a side face of the cooler 3. The cooler 3 also contains through holes 3c which pass through in a thickness direction thereof. The through hole 3c is a hole through which a bolt 8 for holding a layered body including the coolers 3, the insulating plates 4, the electrode plates 5 and the semiconductor 6 is to be passed. Further, a dent 3a which is recessed from the surface of the cooler 3 is formed around an opening of the through hole 3c. A nut 7 which is to be engaged with the bolt 8 is embedded in the dent 3a. In the cooler 3 positioned on a far side in FIGS. 1, 2, the dents 3a are provided and a bolt head 8a is embedded in each of the dents 3a. The dent 3a is called spot facing in other words.

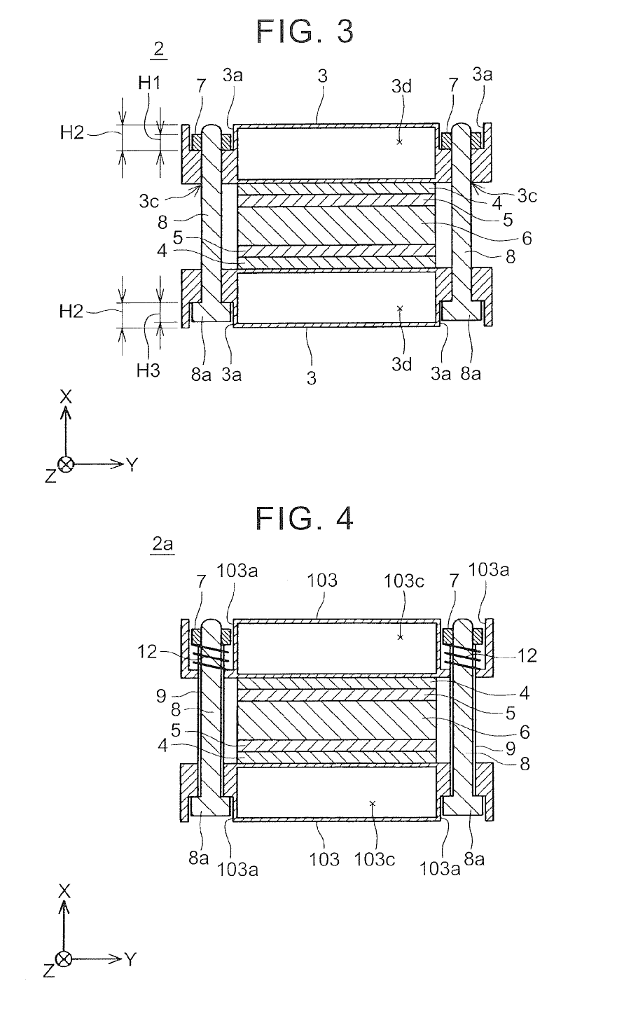

FIG. 3 shows a sectional view of the semiconductor module 2 taken along the line III-III in FIG. 2. As shown in FIG. 3, the layered body including the coolers 3, the insulating plates 4, the electrode plates 5 and the semiconductor device 6 is fastened with the two bolts 8 and the corresponding nuts 7 in a layer direction so that the respective components are fastened to each other. The two bolts 8 are located on both sides of the semiconductor device 6 with respect to the layer direction (X-direction in the Figure). That is, the bolts 8 are located on both sides of the semiconductor device 6 in a direction perpendicular to the layer direction (Y-direction in the Figure). The bolts 8 are not in direct contact with the semiconductor device 6. That is, the bolts 8 are apart from the semiconductor device on a plane perpendicular to the layer direction.

As described previously, the dent 3a is provided around the through hole 3c in the surface on one side of the cooler 3. The bolt head 8a is embedded in the dent 3a of one of the coolers 3 which sandwich the semiconductor device 6, and the nut 7 is embedded in the dent 3a of the other of the coolers 3. As shown in FIG. 3, a height H1 of the nut 7 is lower than a depth H2 of the dent 3a and a height H3 of the bolt head 8a is lower than a depth H2 of the dent 3a. That is, both the nut 7 and the bolt head 8a are entirely included in the dent 3a so that the nut 7 and the bolt head 8a sink below the surface of the cooler 3.

Both the bolt head 8a and the nut 7 contact the cooler 3 directly. More in detail, both the bolt head 8a and the nut 7 contact the bottom surface of the dent 3a directly. Thus, both the bolt head 8a and the nut 7 are cooled by the cooler 3 directly and their surroundings thereof are covered with layers of air cooled by the cooler 3. In the meantime, reference numeral 3d in FIG. 3 denotes internal space of the cooler 3, indicating a flow passage of coolant.

Due to the above-described structure, even if the temperature of the surrounding (ambient temperature) around the semiconductor module 2 is high, the temperatures of the bolt head 8a and the nut 7 do not rise to the ambient temperature. In other words, the range of temperature change of the bolt head 8a and the nut 7 can be smaller than that of the ambient temperature. There is a possibility that the nut 7 may be loose from the bolt 8 when the temperature change of the nut 7 is large. On the other hand, the semiconductor module 2 of the present embodiment is capable of suppressing the range of temperature change of the nut 7, and thus the possibility that the nut 7 may be loose can be reduced. Particularly, because the nut 7 has entirely sunk into the dent 3a of the cooler 3, the dent 3a is filled with air cooled by a side face of the dent 3a so that the cooled air covers the nut 7. Because the nut 7 is covered with layers of the cooled air, it is unlikely to be affected by an outside temperature.

A direct contact of the nut 7 with the bottom surface of the dent 3a in the cooler 3 also contributes to prevention of increase in the temperature of the nut 7.

Further, the bolts 8 are located on both sides of the semiconductor device 6 with respect to the layer direction, without contacting the semiconductor device 6. Although the semiconductor device 6 generates heat, that heat is not transmitted directly to the bolts 8. Furthermore, because the bolts 8 are not in contact with the semiconductor device 6 so that the bolts 8 are not heated by the semiconductor device 6, increase in the temperature of the nuts 7 is prevented.

FIG. 4 shows a sectional view of a semiconductor module 2a according to a second embodiment. In the semiconductor module 2a, a coil spring 12 is arranged between the nut 7 and the bottom surface of a dent 103a provided in the cooler 103. In the meantime, the dent 103a provided in the cooler 103 is deeper than the dent 3a in the aforementioned cooler 3 by an amount corresponding to insertion of the coil spring 12.

In the semiconductor module 2a, the coil spring 12 is arranged between the nut 7 and the bottom surface of the dent 103a provided in the cooler 103, and then, the coil spring 12 applied a load which pressurizes the layered body (layered body including the coolers 103, the insulating plates 4, the electrode plates 5 and the semiconductor device 6) in the layer direction. Thus, even if the nut 7 becomes loose to some extent, the load which pressurizes the layered body hardly changes, so that a constant load can be applied continuously to the layered body. The bolt 8 is provided with a collar (cylinder) 9. The collar 9 prevents a sliding between threads of the bolt 8 and the coil spring 12.

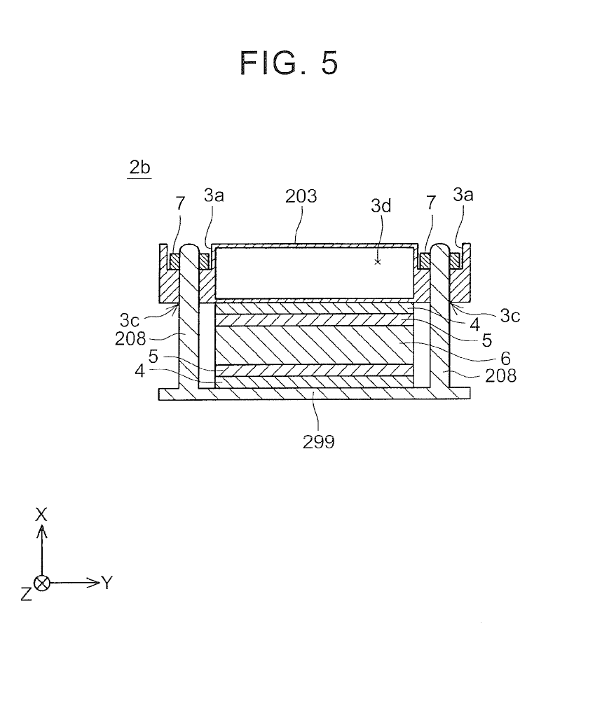

FIG. 5 shows a sectional view of a semiconductor module 2b according to a third embodiment. In the semiconductor module 2b of the third embodiment, the cooler 203 is arranged on one side of the semiconductor device 6 and a metallic plate 299 is arranged on the other side thereof. The cooler 203 is identical to the cooler 3 of the first embodiment. Two bolts 208 are fixed to the metallic plate 299. The semiconductor module 2b is identical to the semiconductor module 2 of the first embodiment in that the nut 7 is screwed with a front end of the bolt 208 and that the dent 3a for accommodating the nut 7 is provided in the cooler 3. Thus, a surrounding of the nut 7 is covered with layers of air cooled by the cooler 203 preventing an increase in temperature of the nut 7 as in the semiconductor module 2 of the first embodiment.

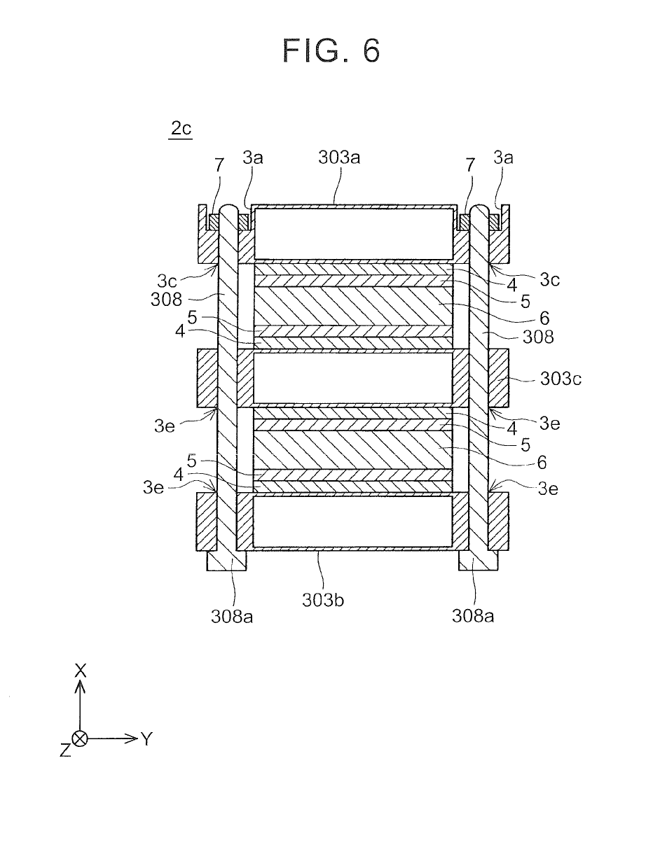

FIG. 6 shows a sectional view of a semiconductor module 2c of a fourth embodiment. The semiconductor module 2c has a structure in which three coolers 303a, 303b, 303c and two semiconductor devices 6 are layered on each other alternately. Long bolts 308 and nuts 7 fasten the layered body including the three coolers 303a and the two semiconductor devices 6 from both sides. The coolers 303a are arranged on both sides of each of the two semiconductor devices 6 so as to be adjacent to the each of the two semiconductor devices 6 (across the electrode plate 5 and the insulating plate 4). The cooler 303a has the same structure as the upper cooler 3 in FIG. 3 and has the dent 3a for accommodating the nut 7. Thus, a surrounding of the nut 7 is covered with layers of air cooled by the cooler 303a preventing an increase in temperature of the nut 7 as in the semiconductor module 2 of the first embodiment.

The cooler 303b and the cooler 303c have the same structure and have through holes 3e which the bolt 308 passes. The cooler 303b located on the bottommost in FIG. 6 has no dent for accommodating the bolt head 308a unlike the cooler 303a. The semiconductor module 2c is suitable for an environment in which although a heating element exists in the vicinity of the nut 7 so that the ambient temperature nearby is high, no heating element exists on the bolt head side so that the ambient temperature of the bolt head 308a is not so high as in the circumstance of the nut 7.

The points of attention concerning the semiconductor module described in the embodiments will be mentioned here. The bolt 8 and the nut 7 may be regarded as an example of the fastening member. The nut 7 may be regarded as an example of a pressure contact part. Instead of the bolt 8 having the bolt head 8a, a rod provided with male screws on both sides thereof may be used. Further, instead of the coil spring 12, a spring washer may be used.

In the semiconductor module 2, 2a of the embodiments, the nut 7 and the bolt head 8a sink in the dent 3a or dent 103a provided in the cooler 3 or the cooler 103. Preferably, the dent 3a or dent 103a has a depth sufficient for the nut 7 entirely to sink therein. However, even if the depth of the dent 3a or dent 103a is just to an extent covering a part of the nut 7, the aforementioned effect can be obtained although there is a difference depending on the extent. That is, even if the depth of the dent 3a or dent 103a is just to the extent covering a part of the nut 7, such a dent is included in part of technology disclosed in the present specification.

In the semiconductor module 2b of the third embodiment, the cooler 203 is arranged only on one side of the semiconductor device 6 and the metallic plate 299 provided with the two bolts 208 extending therefrom is arranged on the opposite side. A member for pressurizing an end of the layered body of the semiconductor module 2b may be a wall of a casing or a casing of other device which accommodates the semiconductor module 2b instead of the metallic plate 299. Instead of the metallic plate 299, it is permissible to use a cooler provided with two bolts extending therefrom.

In the semiconductor module 2c of the fourth embodiment, the three coolers and the two semiconductor devices are layered on each other alternately. The number of the coolers and semiconductors to be layered is not limited to those of the aforementioned embodiments but may be of any number. In the semiconductor module 2c, no dent for accommodating the bolt head 308a is provided in the cooler 303b. As described above, the technology disclosed in the present specification just requires the coolers having the dent for accommodating the nut to be arranged on at least one side of a flat semiconductor device. The cooler 308b may be provided with a dent for accommodating the bolt head 308a. Further instead of the bolt 308 and the cooler 303b, it is permissible to use a cooler provided with a bolt extending therefrom. Still further, instead of the bolt 308 and the cooler 303b, it is permissible to use a plate provided with the bolt extending therefrom like the metallic plate 299 of the third embodiment.

As described above, the dent provided in the cooler is filled with air cooled by the cooler. That is, layers of air cooled by the cooler are formed around the pressure-contact part. Thus, in an environment where an engine or a motor exists nearby the semiconductor module so that the ambient temperature changes violently, a temperature change at the pressure-contact part is relaxed.

As described above, the cooler may be arranged only on one side of the semiconductor or may be arranged on both sides. In case where the cooler is arranged only on one side of the semiconductor device, a member which holds the semiconductor device together with the cooler is arranged on an opposite side to the cooler. The member which holds the semiconductor device may be a metallic plate or a resin plate. Alternatively, it may be a side wall of a housing which accommodates the semiconductor device or another device. In case where the coolers are arranged on both sides of the semiconductor device, if the dent for accommodating the pressure-contact part is provided at least in one cooler, the aforementioned effect can be expected. Of course, it is preferable that the dents are provided in the both coolers.

The pressure-contact part is more preferred to contact the cooler directly. This is because the pressure-contact part is directly cooled by the cooler.

As described above, the fastening member is typically a bolt and a nut, and the pressure-contact part is typically a nut which is screwed with the bolt to apply a load to the cooler. The nut is expanded/contracted due to a temperature change. Thus, if the temperature change of the nut is violent, there is a possibility that the nut may be loose. If the nut becomes loose, adhesion between the semiconductor device and the cooler is decreased so that efficiency of heat transfer from the semiconductor device to the cooler is decreased. With the above-described structure, the temperature change of the nut is suppressed thereby decreasing a possibility that the nut may be loose. Further, to protect the nut from changes of outside temperature, the depth of the dent in the cooler is preferred to be as high as a height of the nut or larger than the height of the nut.

As described above, it is preferable that the bolt is not in contact with the semiconductor device. This is because heat from the semiconductor device can be prevented from being transferred to the bolt.

As described above, it is preferable that a compression spring is arranged between the bottom surface of the dent and the nut. Although the compression spring may be a coil spring, it may be also a spring washer. As for the reason, even if the nut becomes loose, the compression spring can continue to apply a constant pressure to the layered body.

Although the specific embodiments of the present invention have been described in detail, they are just examples thereof. The present invention includes various modifications, alterations and combinations of the specific embodiments described above.

What is claimed is:

1. A semiconductor module comprising:
a semiconductor device having a flat shape;
at least one cooler arranged adjacent to the semiconductor device; and
at least one fastening member having a pressure-contact part configured to apply a pressure to the at least one cooler, the at least one fastening member fastening a layered body including the semiconductor device and the at least one cooler in a layer direction of the layered body, wherein
a dent configured to accommodate the pressure-contact part is provided in the at least one cooler.

2. The semiconductor module according to claim 1, wherein
the at least one cooler is constituted by a first cooler and a second cooler,
the first cooler and the second cooler are arranged on both sides of the semiconductor device in the layer direction, and
at least one of the first cooler and the second cooler is provided with the dent.

3. The semiconductor module according to claim 1, wherein
the pressure-contact part is in contact with the at least one cooler.

4. The semiconductor module according to claim 1, wherein
the at least one fastening member is apart from the semiconductor device.

5. The semiconductor module according to claim 4, wherein
the at least one fastening member is apart from the semiconductor device in a plane perpendicular to the layer direction.

6. The semiconductor module according to claim 1, wherein
the at least one fastening member includes a bolt and a nut, and
the pressure-contact part is the nut.

7. The semiconductor module according to claim 6, wherein
a depth of the dent is larger than a height of the nut.

8. The semiconductor module according to claim 6, further comprising
a compression spring arranged between the nut and the bottom surface of the dent.

9. The semiconductor module according to claim 8, wherein
a depth of the dent is larger than a sum of heights of the nut and the spring.

10. The semiconductor module according to claim 1, wherein
the at least one fastening member is constituted by a first fastening member and a second fastening member, and
the first fastening member and the second fastening member are arranged on both sides of the semiconductor device in a direction perpendicular to the layer direction.

11. The semiconductor module according to claim 1 further comprising:
a electrode plate arranged between the semiconductor device and the at least one cooler in the layer direction and in direct contact with the semiconductor device; and
an insulator plate arranged between the electrode plate and the at least one cooler in the layer direction.

12. The semiconductor module according to claim 1, wherein
the at least one cooler s a hollow member containing a coolant passage.
